(19) United States
(12) Patent Application Publication
(10) Pub. No.: US 2014/0035441 A1
(43) Pub. Date: Feb. 6, 2014

(54) VIBRATION PIECE, ELECTRONIC DEVICE AND ELECTRONIC APPARATUS

(71) Applicant: SEIKO EPSON CORPORATION, Tokyo (JP)

(72) Inventor: Soh ICHIKAWA, Okaya-shi (JP)

(73) Assignee: SEIKO EPSON CORPORATION, Tokyo (JP)

(21) Appl. No.: 13/957,930

(22) Filed: Aug. 2, 2013

(30) Foreign Application Priority Data
Aug. 6, 2012 (JP) 2012-173748

(51) Int. Cl. H01L 41/047

(52) U.S. Cl. CPC H01L 41/047
USPC 310/365

(57) ABSTRACT

A vibration piece includes a pair of base sections which are disposed with spaces in between each other, and a pair of vibration arms which are disposed between the pair of base sections. In addition, the vibration arms, respectively have three vibration areas of a pair of end areas positioned on both ends in an extending direction and a center area positioned between the end areas. Electrode pieces straddling from the side surfaces of the vibration arms to a main surface are disposed in the areas, respectively. An average width of portions of the electrode pieces positioned on the main surface which are disposed in the end areas is greater than an average width of portions of the electrode pieces positioned on the main surface which are disposed in the center area.

### BACKGROUND

1. Technical Field

The present invention relates to a vibration piece, an electronic device and an electronic apparatus.

2. Related Art

As a pressure sensor, a configuration in which a double-ended tuning fork vibration piece is bonded to a diaphragm is known in the related art. In the pressure sensor having such a configuration, a vibration piece is deformed with the diaphragm by a pressure which is applied and the size of the pressure applied to the pressure sensor is detected by measuring a resonance frequency of the vibration piece that varies in response to the degree of the deformation (for example, see JP-A-2007-171123).

The vibration piece has a pair of base sections and a pair of vibration arms connecting the pair of base sections, and a first electrode piece and a second electrode piece are disposed in each of the vibration arms. The first and second electrode pieces are formed to be positioned alternately in the extending direction and the circumferential direction of each of the vibration arms, respectively, and are disposed to be opposite to each other in one vibration arm and the other vibration arm. It is known that vibration efficiency of the vibration arm is increased by such a disposition.

However, in the vibration piece disclosed in JP-A-2007-171123, a width of a portion straddling on a main surface of the electrode piece (the first electrode piece in one vibration arm and the second electrode piece in the other vibration arm) which is disposed on the side surface of vibration areas (end areas) positioned on both ends of each of the vibration arms and a width of a portion straddling on the main surface of the electrode piece (the second electrode piece in one vibration arm and the first electrode piece in the other vibration arm) which is disposed on the side surface of the vibration area (center area) positioned on the center portion of the vibration arm are relatively narrow, respectively, and have a substantially equal configuration with each other. According to this configuration, the electrode piece disposed on the side surface of the end areas is divided in the extending direction of the vibration arm and then the disconnection caused by the division occurs during the manufacturing (patterning the first and second electrode pieces).

Describing in detail, manufacturing of the electrode piece includes a process for forming a resist pattern on a metal film formed on a surface of the vibration arm using a photolithography technique and a process for removing the metal film which is exposed from the resist pattern using an etching technique. The resist pattern is formed by irradiating an exposure light on a positive type photo-resist film coated on the metal film and by removing the photo-resist film of a portion irradiated with the exposure light during the development. It is also necessary to irradiate the exposure light on the side surface (particularly, the side surface of the base section connecting between inner side surfaces of each of the vibration arms) of the vibration arm. At this time, the exposure light reflected on the side surfaces of the base section is irradiated in a vicinity of a boundary portion of the side surfaces of the end area of each of the vibration arms or the side surface of the main surface, which is a location in which the exposure light is not irradiated normally. As a result, the resist pattern of which a part is deficient unintentionally is formed. When performing the etching using such a resist pattern, the electrode piece formed on the side surface of the end area is divided in the extending direction of the vibration arm and this causes the disconnection.

### SUMMARY

An advantage of some aspects of the invention is to provide a vibration piece which can prevent or control disconnection, particularly, disconnection during the manufacturing, an electronic device and an electronic apparatus including the vibration piece.

The invention can be implemented as the following forms or application examples.

### Application Example 1

This application example is directed to a vibration piece including: two base sections which are disposed with spaces in between each other; and a vibration arm which is disposed between the two base sections to extend from one base section to the other base section and to connect the two base sections, and has vibration areas including a pair of end areas positioned on both end sides in an extending direction and a center area positioned between the pair of end areas, in which electrode pieces, which straddle from a side surface of the vibration arm to a main surface connecting with the side surface, is disposed in the pair of the end areas and the center area, respectively, and an average width of the electrode pieces on the main surface in the end areas is greater than an average width of the electrode pieces on the main surface in the center area.

With this configuration, for example, even though a portion of the end areas of the electrode piece which is formed on the side surface of the vibration arm is unintentionally removed when manufacturing the vibration piece, since the conductivity is maintained by the end portion of the straddling section which straddles on the main surface, unintentional disconnection can be prevented.

### Application Example 2

In the vibration piece according to the application example, it is preferable that the widths of the electrode pieces of the main surfaces in the end areas and the center area are constant along the extending direction of the vibration arm.

With this configuration, unintentional disconnection is prevented and the vibration of the vibration arm is stable during the manufacturing process.

### Application Example 3

In the vibration piece according to the application example, it is preferable that, when the average width of the widths of the electrode pieces on the main surface in the end areas is W and the average width of the end areas of the vibration arm is W′, a relationship of 0<W≦W′/6 is satisfied.

With this configuration, the unintentional disconnection can be prevented during manufacturing while the vibration efficiency of the vibration arm is maintained high enough.

### Application Example 4

In the vibration piece according to the application example, it is preferable that the average width of the electrode piece on the main surface is 7.5 μm or more.

With this configuration, the unintentional disconnection can be prevented further reliably during the manufacturing.

### Application Example 5

In the vibration piece according to the application example, it is preferable that the vibration area is configured with three areas of the pair of end areas and the center area.

With this configuration, the vibration arm can be vibrated further efficiently.

### Application Example 6

This application example is directed to an electronic device including: two base sections which are disposed with spaces in between each other; and a vibration arm which is disposed to extend from one base section to the other base section between the two base sections and connects the two base sections, and has vibration areas including a pair of end areas positioned on both end sides in an extending direction and a center area positioned between the pair of end areas, in which an electrode piece, which straddles on a main surface connecting a side surface from the side surface of the vibration arm, is disposed in the pair of the end areas and the center area, respectively, and an average width of the electrode pieces on the main surface in the end areas is greater than an average width of the electrode pieces on the main surface in the center area.

With this configuration, the electronic device having high reliability is obtained.

### Application Example 7

In the electronic device according to the application example, it is preferable that the electronic device is a pressure detecting element including a diaphragm layer having a diaphragm, and the vibration piece which is fixed to the diaphragm.

With this configuration, the electronic device is the pressure detecting element having high reliability.

### Application Example 8

This application example is directed to an electronic apparatus including: two base sections which are disposed with spaces in between each other; and a vibration arm which is disposed to extend from one base section to the other base section between the two base sections and connects the two base sections, and has a vibration area including a pair of end areas positioned on both end sides in an extending direction and a center area positioned between the pair of end areas, in which an electrode piece, which straddles on a main surface connecting a side surface from the side surface of the vibration arm, is disposed in the pair of the end areas and the center area, respectively, and an average width of the electrode piece on the main surface in the end areas is greater than an average width of the electrode piece on the main surface in the center area.

With this configuration, the electronic apparatus having high reliability is obtained.

### BRIEF DESCRIPTION OF THE DRAWINGS

The invention will be described with reference to the accompanying drawings, wherein like numbers reference like elements.

FIG. 1 is a perspective view illustrating a pressure sensor according to a first embodiment of the invention.

FIG. 2 is an exploded perspective view of the pressure sensor illustrated in FIG. 1.

FIGS. 3A and 3B are plan views of a vibration piece included in the pressure sensor illustrated in FIG. 1, FIG. 3A is a top view and FIG. 3B is a transparent view of a lower surface thereof.

FIG. 4A is a cross-sectional view taken along line A-A in FIG. 3A, FIG. 4B is a cross-sectional view taken along line B-B in FIG. 3A and FIG. 4C is a cross-sectional view taken along line C-C in FIG. 3A.

FIG. 5 is a partial enlarged plan view of the vibration piece illustrated in FIGS. 3A and 3B.

FIGS. 6A and 6B are cross-sectional views describing operations of the pressure sensor illustrated in FIG. 1.

FIG. 7 is a perspective view describing a manufacturing method of the pressure sensor.

FIG. 8 is a perspective view describing the manufacturing method of the pressure sensor.

FIG. 9 is a perspective view describing the manufacturing method of the pressure sensor.

FIG. 10 is a perspective view illustrating a configuration of a mobile type (or notebook type) personal computer to which an electronic apparatus including an electronic device according to the invention is applied.

FIG. 11 is a perspective view illustrating a configuration of a cellular phone (also including PHS) to which the electronic apparatus including the electronic device according to the invention is applied.

FIG. 12 is a perspective view illustrating a configuration of a digital still camera to which the electronic apparatus including the electronic device according to the invention is applied.

FIG. 13 is a perspective view illustrating a configuration of a mobile (vehicle) to which the electronic apparatus including the electronic device according to the invention is applied.

### DESCRIPTION OF EXEMPLARY EMBODIMENTS

Hereinafter, a vibration piece, an electronic device and an electronic apparatus according to the invention are described in detail, based on embodiments illustrated in the accompanying drawings.

### First Embodiment

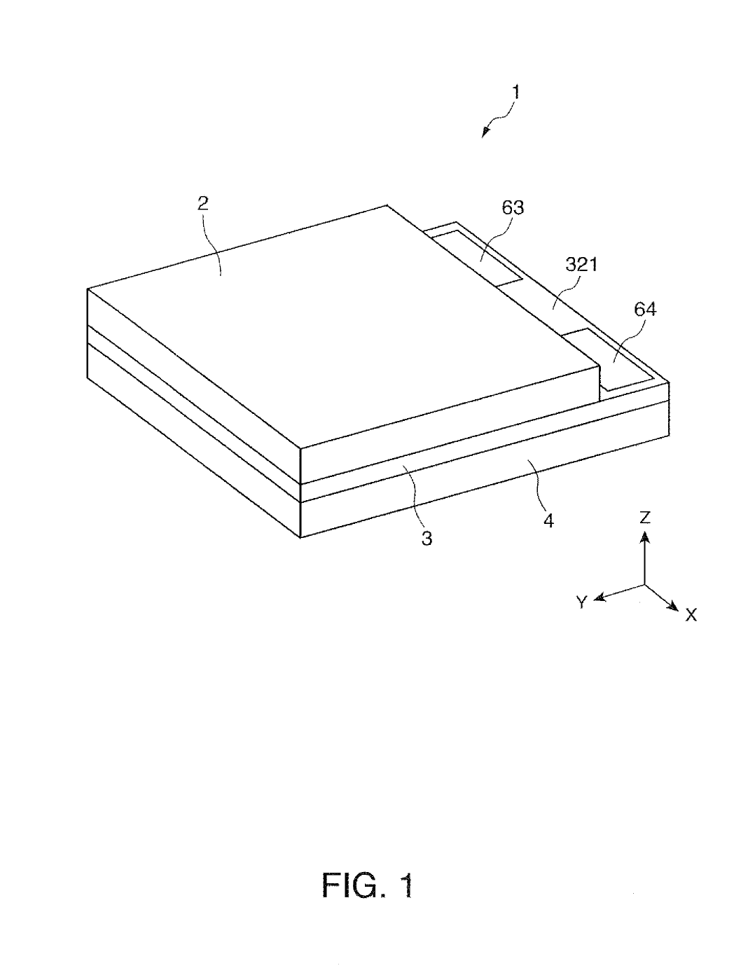

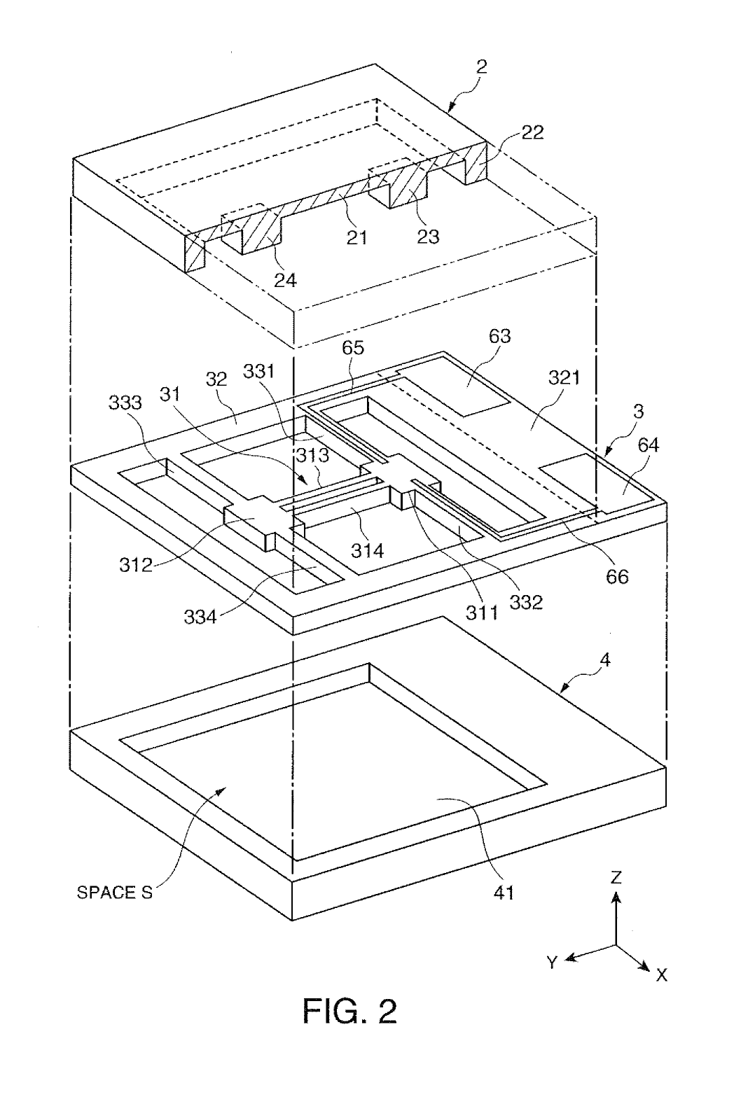

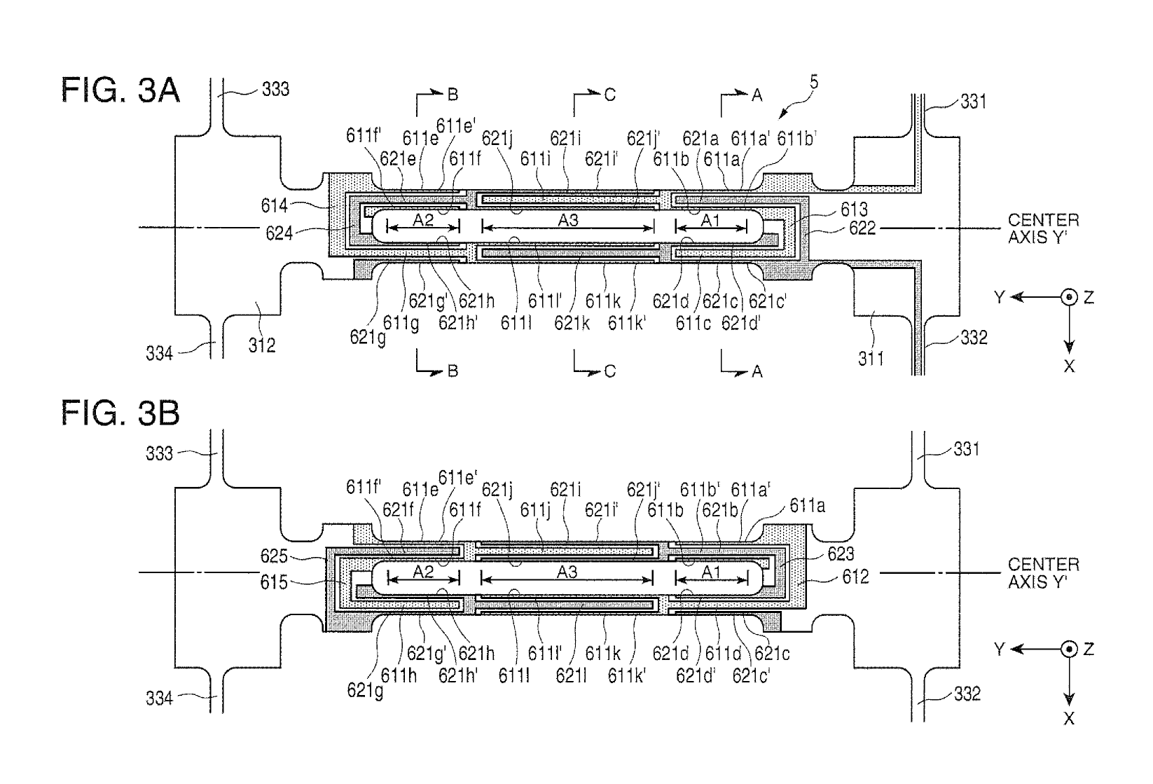

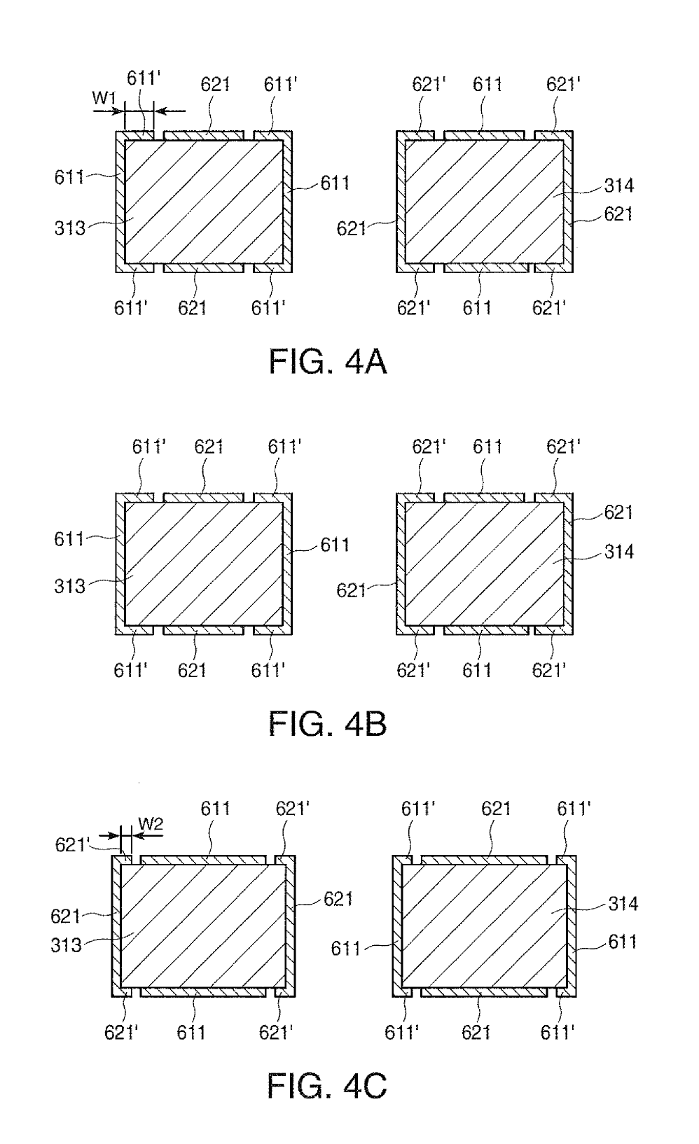

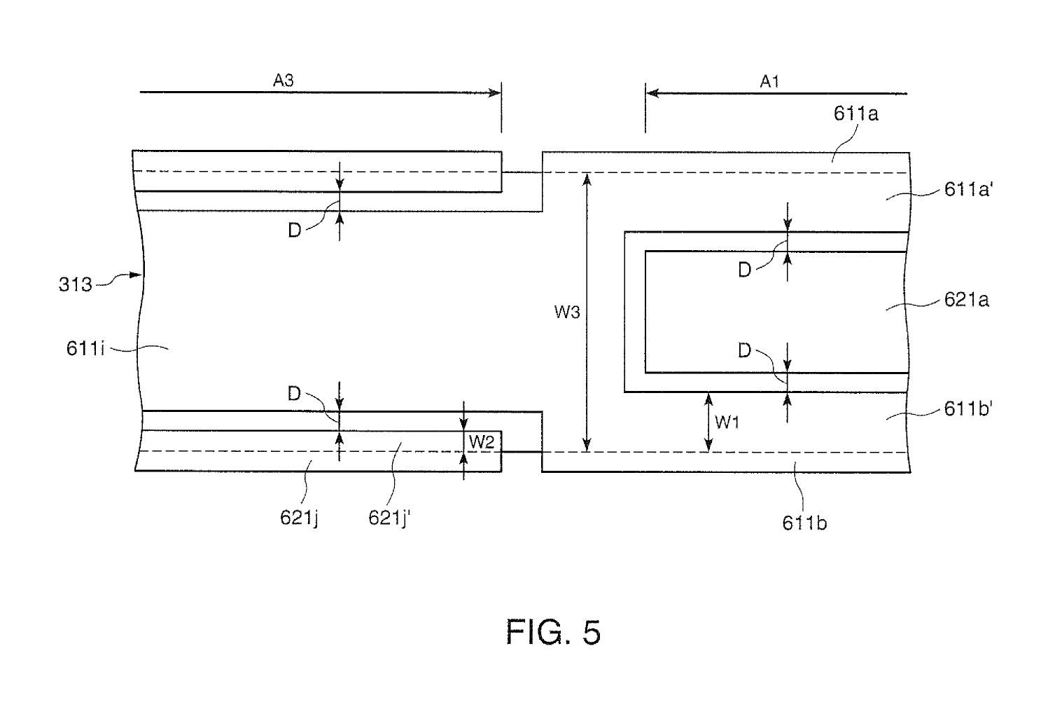

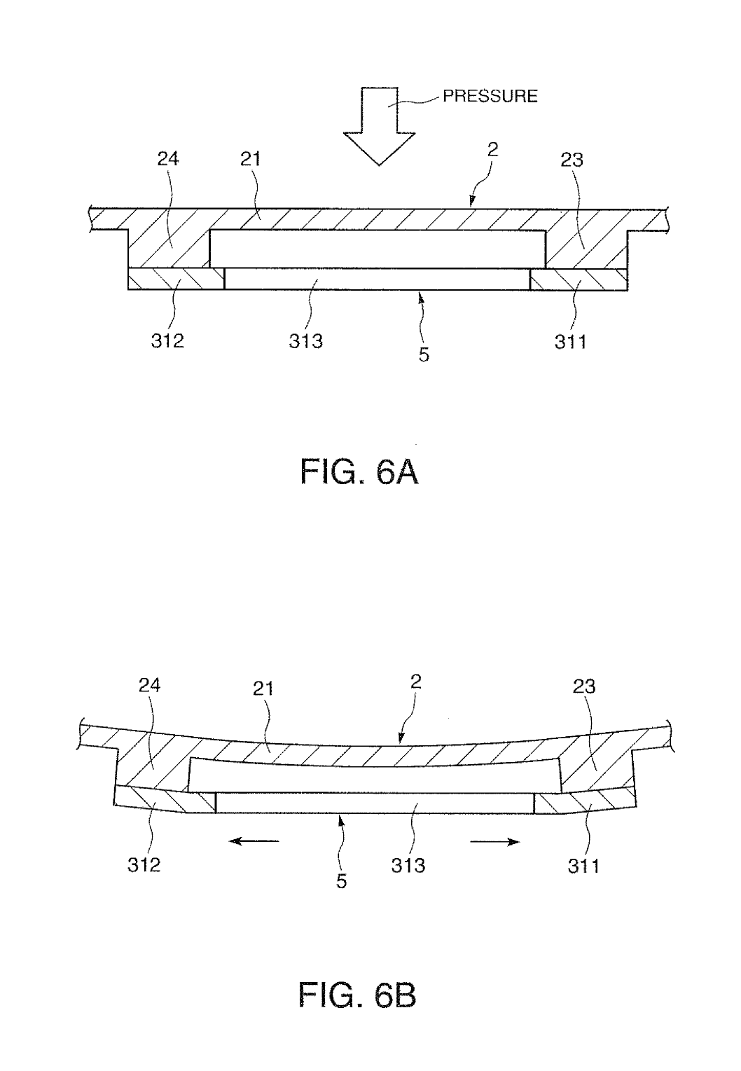

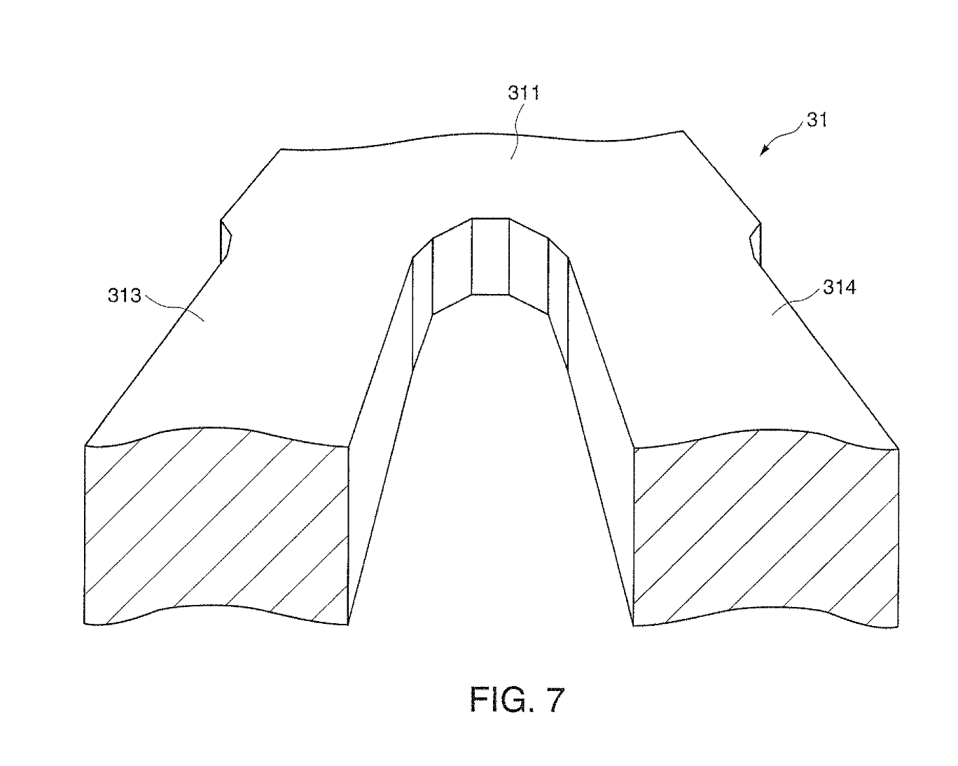

FIG. 1 is a perspective view illustrating a pressure sensor according to a first embodiment of the invention, FIG. 2 is an exploded perspective view of the pressure sensor illustrated in FIG. 1, FIGS. 3A and 3B are plan views of a vibration piece included in the pressure sensor illustrated in FIG. 1, FIG. 3A is a top view and FIG. 3D is a transparent view of a lower surface thereof, FIG. 4A is a cross-sectional view taken along line A-A in FIG. 3A, FIG. 4B is a cross-sectional view taken along line B-B in FIG. 3A and FIG. 4C is a cross-sectional view taken along line C-C in FIG. 3A, FIG. 5 is a partial enlarged plan view of the vibration piece illustrated in FIGS. 3A and 3B, FIGS. 6A and 6B are cross-sectional views illustrating operations of the pressure sensor in FIG. 1, FIGS. 7, 8 and 9 are perspective views describing a manufacturing method of the pressure sensor. In addition, in the description below, an upper side is referred to as “upper” and a lower side is referred to as “lower” in FIG. 1. This will be described correspondingly in the other drawings. Furthermore, hereinafter, as illustrated in FIG. 1, three axes orthogonal to each other are referred to as X axis, Y axis and Z axis, and Z axis is an axis according with a thickness direction of the pressure sensor.

As illustrated in FIGS. 1 and 2, a pressure sensor 1 has a diaphragm layer 2, a vibration body layer 3 in which a vibration piece 5 (a vibration piece according to the invention) as a vibration body 31 is made and a base layer 4, and is configured by laminating the three layers 2, 3 and 4.

It is preferable that the diaphragm layer 2, the vibration body layer 3 and the base layer 4 are configured of quartz crystal, respectively. In this way, unintentional warpage or deflection of the vibration piece 5 generated by difference in the linear expansion coefficient between layers can be suppressed and accuracy of pressure detection of the pressure sensor 1 can be improved by configuring the diaphragm layer 2, the vibration body layer 3 and the base layer 4 with the same material. Particularly, the pressure sensor 1 having excellent temperature characteristics and vibration characteristics is provided by configuring the vibration body layer 3 with quartz crystal.

External shapes of the diaphragm layer 2, the vibration body layer 3 and the base layer 4 can be formed of one sheet of quartz crystal plate, respectively using, for example, photolithography technique and various etching techniques such as dry etching and wet etching.

The diaphragm layer 2, the vibration body layer 3 and the base layer 4 are bonded to each other using a low melting point glass. Herein, the low melting-point glass is not particularly limited; however, it is preferable that vanadium-based low melting-point glass be used of which linear expansion coefficient is close to that of quartz crystal. Accordingly, the unintentional warpage or deflection of the vibration piece 5 caused by difference in the linear expansion coefficient between each of the layers 2, 3 and 4, and the low melting-point glass can be suppressed.

In addition, it is preferable that the low melting-point glass include a particulate spacer. Therefore, unintentional warpage or deflection of the vibration piece 5 caused by difference in the linear expansion coefficient between each of the layers 2, 3 and 4, and the low melting-point glass can be effectively suppressed. In addition, bonding of the diaphragm layer 2, the vibration body layer 3 and the base layer 4 may use various adhesives or metal-metal bonding such as Au—Au in the place of the low melting-point glass.

### Diaphragm Layer

The diaphragm layer 2 has a thin section 21 which is deformed by receiving pressure from outside and a frame section 22 which is formed around the thin section 21. Furthermore, the diaphragm layer 2 has a pair of support sections 23 and 24 which protrude from a lower surface of the thin section 21 and are spaced from each other in a Y axis direction. The vibration piece 5 is fixed to the pair of support sections 23 and 24 via the low melting-point glass.

### Base Layer

The base layer 4 is provided to face the diaphragm layer 2 via the vibration body layer 3. The base layer 4 has a concave section 41 which opens in the upper surface. The concave section 41 faces a concave section (the thin section 21) formed on the diaphragm layer 2 so that a space S is formed and the vibration piece 5 is positioned in the space S.

It is preferable that the space S be a vacuum state. The space S is the vacuum state so that it is possible to decrease CI (Crystal Impedance) value of the vibration piece 5 and improve frequency stability thereof. In addition, in order to make the space S the vacuum state, a method in which the diaphragm layer 2, the vibration body layer 3 and the base layer 4 are bonded in the vacuum state (under vacuum environment) or a method in which after forming a through hole in the base layer 4 and bonding the diaphragm layer 2, the vibration body layer 3 and base layer 4 under ordinary pressure, the space S is turned into the vacuum state through the through hole and a filler (AuS, AuGe or the like) is filled in the through hole and the through hole is sealed is included.

### Vibration Body Layer

The vibration body layer 3 is disposed between the diaphragm layer 2 and the base layer 4. The vibration body layer 3 has a vibration body 31 (the vibration piece 5), a frame-shaped frame section 32 which is provided to surround around the vibration body 31, and four connecting sections 331, 332, 333 and 334 connecting the vibration body 31 and the frame section 32.

The frame section 32 has an exposed section 321 exposed from the diaphragm layer 2 from a plan view which is seen from the diaphragm layer 2 side. The exposed section 321 has conductive pads 63 and 64 described below which are spaced from each other and provided side by side in an X axis direction.

The vibration body 31 has two base sections 311 and 312 which are disposed with spaces in between each other in the Y axis direction and a pair of vibration arms 313 and 314 which connect the base sections 311 and 312.

The vibration arms 313 and 314 are disposed to extend from one side to the other side of the base sections 311 and 312 between the two base sections 311 and 312, respectively. In addition, the vibration arms 313 and 314 are provided parallel to each other at an interval and have a longitudinal shape extending in the Y axis direction. In addition, the number of the vibration arms is not limited to two and may be one or three or more.

The vibration body 31 described above is fixed to the support sections 23 and 24 via the low melting-point glass in the base sections 311 and 312.

The four connecting sections 331 to 334 have a longitudinal shape extending in the X axis direction, respectively. The connecting sections 331 and 332 connect the base section 311 and the frame section 32, and the connecting sections 333 and 334 connect the base section 312 and the frame section 32. In addition, the number of the connecting sections or the extending direction thereof is not particularly limited as long as the vibration body 31 can be connected to the frame section 32. For example, one or three or more connecting sections may be formed with respect to each of the base sections 311 and 312.

A conductive pattern is formed on the vibration body layer 3 having the shape described above. The conductive pattern has a pair of excitation electrodes 61 and 62 which are formed in the vibration body 31, a pair of conductive pads 63 and 64 which are formed in the exposed section 321 of the frame section 32, and wirings 65 and 66 which electrically connect the excitation electrodes 61 and 62 and the conductive pads 63 and 64.

The vibration piece 5 is configured with the vibration body 31 and the excitation electrodes 61 and 62 in the pressure sensor 1. When alternating voltage is applied between the excitation electrodes 61 and 62, the vibration arms 313 and 314 approach and separate from each other repeatedly thereby being vibrated. In particular, a double-ended tuning fork vibration piece such as the vibration piece 5 of the embodiment has good sensitivity with respect to extension and compression stress and has excellent resolution as a pressure sensitive element. Thus, the pressure sensor 1 using the vibration piece 5 can exert excellent pressure sensing ability.

The pair of the excitation electrodes 61 and 62 are disposed so that the vibration piece 5 is vibrated in a state where a vibration mode of the vibration piece 5 is a mode which is symmetrical with respect to a center axis Y′ of the vibration piece 5. FIG. 3A is a top view in which the vibration piece 5 is viewed from the diaphragm layer 2 side and FIG. 3B is a transparent view of a lower surface, in which the vibration piece 5 is viewed from the diaphragm layer 2 side. FIG. 4A is a cross-sectional view taken along line A-A in FIG. 3A, FIG. 4B is a cross-sectional view taken along line B-B in FIG. 3A and FIG. 4C is a cross-sectional view taken along line C-C in FIG. 3A.

As illustrated in FIGS. 3A to 3B and FIGS. 4A to 4C, the excitation electrode 61 has a plurality of electrode pieces 611 formed on the vibration arms 313 and 314, wirings 612 and 613 which are formed on the base section 311 and connect the electrode pieces 611 formed in the vibration arm 313 and the electrode pieces 611 formed in the vibration arm 314, and wirings 614 and 615 which are formed on the base section 312 and connect the electrode pieces 611 formed in the vibration arm 313 and the electrode pieces 611 formed in the vibration arm 314.

In the same way, the excitation electrode 62 has a plurality of electrode pieces 621 formed on the vibration arms 313 and 314, wirings 622 and 623 which are formed on the base section 311 and connect the electrode pieces 621 formed in the vibration arm 313 and the electrode pieces 621 formed in the vibration arm 314, and wirings 624 and 625 which are formed on the base section 312 and connect the electrode pieces 621 formed in the vibration arm 313 and the electrode pieces 621 formed in the vibration arm 314.

The electrode pieces 611 and 621 are formed so as to alternately position in a longitudinal direction and a circumferential direction of the vibration arms 313 and 314, respectively, and are formed so that arrangement of the vibration arm 313 and the vibration arm 314 are reversed.

In addition, three electrode pieces 611 and 621 are formed alternately along the longitudinal direction of the vibration arms 313 and 314. Thus, the vibration arms 313 and 314 can be divided into three vibration areas along the longitudinal direction (the extending direction), thereof corresponding to the arrangement of the electrode pieces 611 and 621. In particular, the vibration arms 313 and 314 can be divided into a first end area (an end area) A1 including a cross section of FIG. 4A, a second end area (an end area) A2 including a cross section of FIG. 4B and a center area A3 including a cross section of FIG. 4C and being positioned between the first and second end areas A1 and A2.

As described above, the vibration arms 313 and 314 have the vibration areas configured with three areas A1 to A3 so that the vibration arms 313 and 314 can be vibrated further efficiently. Therefore, sensitivity thereof as the pressure sensor is excellent.

Hereinafter, electrode arrangement in each area of the first end area A1, the second end area A2 and the center area A3 will be sequentially described in detail.

### First End Area A1

Electrode pieces 621a and 621b are formed on the upper surface and the lower surface of the vibration arm 313, and electrode pieces 611a and 611b are formed on both side surfaces thereof. In addition, the electrode pieces 611a and 611b are formed across the upper surface and the lower surface of the vibration arm 313. Accordingly, the electrode pieces 621a and 621b are formed at the center portion in the width direction on the upper surface and the lower surface of the vibration arm 313, and the electrode pieces 611a and 611b are formed at both ends holding the electrode pieces 621a and 621b inbetween. In addition, the electrode pieces 621a and 621b have substantially constant widths along the Y axis direction, respectively, and the widths thereof are the same as each other. In addition, the electrode pieces 611a and 611b (straddling sections 611a′ and 611b′) on main surfaces (the upper surface and the lower surface) have substantially constant widths along the Y axis direction, respectively, and the widths thereof are the same as each other.

On the other hand, electrode pieces 611c and 611d are formed on the upper surface and the lower surface of the vibration arm 314, and electrode pieces 621c and 621d are formed on both side surfaces thereof. In addition, the electrode pieces 621c and 621d are formed across the upper surface and the lower surface of the vibration arm 314. Accordingly, the electrode pieces 611c and 611d are formed at the center portion in the width direction on the upper surface and the lower surface of the vibration arm 314, and the electrode pieces 621c and 621d are formed at both ends holding the electrode pieces 611c and 611d inbetween. In addition, the electrode pieces 611c and 611d have substantially constant widths along the Y axis direction, respectively, and the widths thereof are the same as each other. In addition, the electrode pieces 621c and 621d (straddling sections 621c′ and 621d′) on the main surfaces (the upper surface and the lower surface) have substantially constant widths along the Y axis direction, respectively, and the widths thereof are the same as each other.

In addition, the electrode pieces 611a and 611d are electrically connected to each other via the wiring 612 formed on the lower surface of the base section 311 and the electrode pieces 611b and 611c are electrically connected to each other via the wiring 613 formed on the upper surface of the base section 311. In addition, the electrode pieces 621a and 621c are electrically connected to each other via the wiring 622 formed on the upper surface of the base section 311 and the electrode pieces 621b and 621d are electrically connected to each other via the wiring 623 formed on the lower surface of the base section 311.

### Second End Area A2

Electrode pieces 621e and 621f are formed on the upper surface and the lower surface of the vibration arm 313, and electrode pieces 611e and 611f are formed on both side surfaces thereof. In addition, the electrode pieces 611e and 611f are formed across the upper surface and the lower surface of the vibration arm 313. Accordingly, the electrode pieces 621e and 621f are formed at the center portion in the width direction on the upper surface and the lower surface of the vibration arm 313, and the electrode pieces 611e and 611f are formed at both ends holding the electrode pieces 621e and 621f inbetween. In addition, the electrode pieces 621e and 621f have substantially constant widths along the Y axis direction, respectively, and the widths thereof are the same as each other. In addition, the electrode pieces 611e and 611f (straddling sections 611e′ and 611f′) on main surfaces (the upper surface and the lower surface) have substantially constant widths along the Y axis direction, respectively, and the widths thereof are the same as each other.

On the other hand, electrode pieces 611g and 611h are formed on the upper surface and the lower surface of the vibration arm 314, and electrode pieces 621g and 621h are formed on both side surfaces thereof. In addition, the electrode pieces 621g and 621h are formed across the upper surface and the lower surface of the vibration arm 314. Accordingly, the electrode pieces 611g and 611h are formed at the center portion in the width direction on the upper surface and the lower surface of the vibration arm 314, and the electrode pieces 621g and 621h are formed at both ends holding the electrode pieces 611g and 611h inbetween. In addition, the electrode pieces 611g and 611h have substantially constant widths along the Y axis direction, respectively, and the widths thereof are the same as each other. In addition, the electrode pieces 621g and 621h (straddling sections 621g′ and 621h′) on the main surfaces (the upper surface and the lower surface) have substantially constant widths along the Y axis direction, respectively, and the widths thereof are the same as each other.

In addition, the electrode pieces 611g and 621g are electrically connected to each other via the wiring 614 formed on the upper surface of the base section 312 and the electrode pieces 611f and 611h are electrically connected to each other via the wiring 615 formed on the lower surface of the base section 311. In addition, the electrode pieces 621e and 621h are electrically connected to each other via the wiring 624 formed on the upper surface of the base section 311 and the electrode pieces 621f and 621g are electrically connected to each other via the wiring 625 formed on the lower surface of the base section 311.

### Center Area A3

Electrode pieces 611i and 611j are formed on the upper surface and the lower surface of the vibration arm 313, and electrode pieces 621i and 621j are formed on both side surfaces thereof. In addition, the electrode pieces 621i and 621j are formed across the upper surface and the lower surface of the vibration arm 313. Accordingly, the electrode pieces 611i and 611j are formed at the center portion in the width direction on the upper surface and the lower surface of the vibration arm 313, and the electrode pieces 621i and 621j are formed at both ends holding the electrode pieces 611i and 611j. In addition, the electrode pieces 611i and 611j have substantially constant widths along the Y axis direction, respectively, and the widths thereof are the same as each other. In addition, the electrode pieces 621i and 621j (straddling sections 621i′ and 621j′) on main surfaces (the upper surface and the lower surface) have substantially constant widths along the Y axis direction, respectively, and the widths thereof are the same as each other.

The electrode piece 611i is electrically connected to the electrode pieces 611a and 611b between the first end area A1 and the center area A3 on the upper surface of the vibration arm 313. In addition, the electrode piece 611j is electrically connected to the electrode pieces 611e and 611f between the second end area A2 and the center area A3 on the lower surface of the vibration arm 313. In addition, the electrode pieces 621i and 621j are electrically connected to the electrode piece 621e between the second end area A2 and the center area A3 on the upper surface of the vibration arm 313.

On the other hand, electrode pieces 621k and 621l are formed on the upper surface and the lower surface of the vibration arm 314, and electrode pieces 611k and 611l are formed on both side surfaces thereof. In addition, the electrode pieces 611k and 611l are formed across the upper surface and the lower surface of the vibration arm 314. Accordingly, the electrode pieces 621k and 621l are formed at the center portion in the width direction on the upper surface and the lower surface of the vibration arm 314, and the electrode pieces 611k and 611l are formed at both ends holding the electrode pieces 621k and 621l inbetween. In addition, the electrode pieces 621k and 621l have substantially constant widths along the Y axis direction, respectively, and the widths thereof are the same as each other. In addition, the electrode pieces 611k and 611l (straddling sections 611k′ and 611l′) on the main surfaces (the upper surface and the lower surface) have substantially constant widths along the Y axis direction, respectively, and the widths thereof are the same as each other.

In addition, the electrode piece 621k is electrically connected to the electrode pieces 621c and 621d between the first end area A1 and the center area A3 on the upper surface of the vibration arm 313. In addition, the electrode piece 621l is electrically connected to the electrode pieces 621g and 621h between the second end area A2 and the center area A3 on the lower surface of the vibration arm 313. In addition, the electrode pieces 611k and 611l are electrically connected to the electrode piece 611g between the second end area A2 and the center area A3 on the upper surface of the vibration arm 313.

Hereinbefore, the configuration of the excitation electrodes 61 and 62 is described in detail. As illustrated in FIG. 5, the vibration piece 5 is configured such that a width (an average width) of the straddling section formed in the first end area A1 (the second end area A2) is greater than a width (an average width) of the straddling section formed in the center area A3. Hereinafter, difference in the widths of the straddling sections 611b′ and 621j′ formed on the upper surface of the vibration arm 313 is described representatively and description of other straddling sections (for example, the straddling sections 611f′ and 621j ‘, the straddling sections 621d’ and 611l′, the straddling sections 621h′ and 611l′ or the like) is omitted.

When the width (the average width) of the straddling section 611b′ is W1, the width (the average width) of the straddling section 621j′ is W2, W1 and W2 satisfy a relationship of W1>W2. W1 and W2 satisfy the relationship of W1>W2 so that it is possible to prevent disconnection of the excitation electrodes 61 and 62 during manufacturing.

As described below, manufacturing process of the vibration piece 5 includes a process for forming the excitation electrodes 61 and 62 on the surface of the vibration body 31. The process includes a process for forming a resist pattern (mask) on a metal film formed on the surface of the vibration body 31 using the photolithography technique and a process for removing the metal film exposed from the resist pattern using the etching technique.

The resist pattern is formed by irradiating exposure light on a positive type photo-resist film applied on the metal film and by removing the photo-resist film in a portion to which the exposure light is irradiated by developing. It is necessary to irradiate the exposure light on a side surface (in particular, a side surface of the base sections 311 and 312 connecting inner side surfaces of each of the vibration arms 313 and 314 and inner side surfaces of the vibration arms 313 and 314 with each other) of the vibration body 31; however, at this time, the exposure light reflected on the side surfaces of the base sections 311 and 312 is irradiated in a vicinity of a boundary portion of the side surfaces of the end areas A1 and A2 of each of the vibration arms 313 and 314 or the side surface of the main surface, which is a location in which the exposure light is not irradiated normally. As a result, the resist pattern of which a part is deficient unintentionally is formed. When etching is performed using the resist pattern, there is a concern that the electrode pieces 611 and 621 formed on the side surfaces of the end areas A1 and A2 may be divided in the extending direction of the vibration arms 313 and 314, and this may cause the disconnection thereof.

However, the relationship of W1>W2 is satisfied so that the disconnection of the excitation electrodes 61 and 62 is prevented because the electrical connection is ensured via the straddling sections 611′ and 621′ formed on the upper surface and the lower surface thereof, even though a part of the metal film (the electrode pieces 611 and 621) on the side surfaces of the end areas A1 and A2 of the vibration arms 313 and 314 is removed unintentionally.

In addition, the value of W1 is not particularly limited; however, it is preferable that the value be 7.5 μm or more. The effects described above can be remarkably exerted by making such a size. Herein, in order to enhance the effect described above, it is preferable to make W1 greater but when W1 is great, the width of the electrode piece 621a formed parallel to the straddling section 611′ is reduced, accordingly. However, if the width of the electrode piece 621a is reduced, the vibration characteristic of the vibration arm 313 is deteriorated. Thus, it is preferable that W1 be approximately ⅙ or less of the width of the vibration arm 313 from the viewpoint of suppressing the deterioration of the vibration characteristic. In other words, when the width (the average width of the first end area) of the vibration arm 313 is W3, it is preferable to satisfy a relationship of 0<W1≦W3/6 and it is further preferable to satisfy a relationship of 7.5<W1≦W3/6. It is preferable that the electrodes disposed on the upper and lower surfaces of the vibration arm satisfy the end area<the center area from the same viewpoint and it is preferable that the widths of the electrode pieces 611(c, d, g and h) and 621(a, b, e and f) of the end area be a half or more of the vibration arm.

In addition, W1 and W2 satisfy the relationship of W1>W2 thereby making the vibration piece 5 having excellent vibration efficiency. Among the first end area A1, the second end area A2 and the center area A3, the center area A3 contributes most to the vibration of the vibration arm 313. Therefore, particularly, it is desirable that the widths of the electrode pieces 611i and 611j formed on the upper surface in the center area A3 and the lower surface of the vibration arm 313 be widely formed to enhance efficiency of the electric field. If the relationship of W1>W2 is satisfied, the width of the straddling section 621j′ is reduced at the center area A3 and then the widths of the electrode pieces 611i and 611j can be widened, accordingly. Therefore, the vibration piece 5 having excellent vibration efficiency is provided.

In addition, in order to enhance the effect described above, it is preferable that W2=0; however, it is preferable to be approximately 2 μm when considering patterning accuracy (formation accuracy of the mask by the photolithography technique) of the electrode pieces 621 during manufacturing. If it is such a value, the disconnection of the excitation electrodes 61 and 62 according to the shift of the mask during manufacturing can be effectively prevented and the effect described above can be sufficiently exerted.

In addition, in each of the areas A1, A2 and A3 in the vibration piece 5, the width of each of the electrode pieces 611 and 621 formed on the upper surface and the lower surface of the vibration arms 313 and 314 is the same along the Y axis direction, the widths of the straddling sections 611′ and 621′ are the same along the Y axis direction and, furthermore, a distance (a distance illustrated as D in FIG. 5) spacing between adjacent electrode pieces in the width direction in the upper surface and the lower surface of the vibration arms 313 and 314 is the same along the Y axis direction. According to such an electrode arrangement, since it is possible to exert a uniform electric field over an entire area of the vibration arms 313 and 314 in the longitudinal direction, the vibration of the vibration arms 313 and 314 is stable. In addition, since it is possible to prevent concentration of electric field to a predetermined place, the excitation electrodes 61 and 62 of which strength can withstand sufficiently to strong excitation are provided.

Hereinbefore, the configuration of the pressure sensor 1 is described. The pressure sensor 1 operates in the following manner. As illustrated in FIG. 6A, when pressure is applied to the diaphragm layer 2, the thin section 21 is deflected so that the lower surfaces of the two support sections 23 and 24 are expanded as illustrated in FIG. 6B. A tensile force is applied to the vibration arms 313 and 314 by the deflection of the thin section 21. Since the vibration piece has characteristics that oscillation frequency increases when tensile stress is given to the vibration arms 313 and 314, an amount of change in the oscillation frequency of the vibration piece 5 is detected and the size of the pressure given to the pressure sensor 1 can be derived, based on the amount of the change in the detected oscillation frequency.

### 2. Manufacturing Method of Vibration Piece

The manufacturing method of the vibration piece 5 has a process for preparing the vibration body 31 and a process for forming the excitation electrodes 61 and 62 on the surface of the vibration body 31.

Firstly, as illustrated in FIG. 7, a quartz crystal plate is prepared and the quartz crystal plate is patterned in a predetermined shape using the photolithography technique and the etching technique (the wet etching) so that the vibration body layer 3 is obtained. A crystal plane of the quartz crystal appears on a side surface of the vibration body 31 which is obtained.

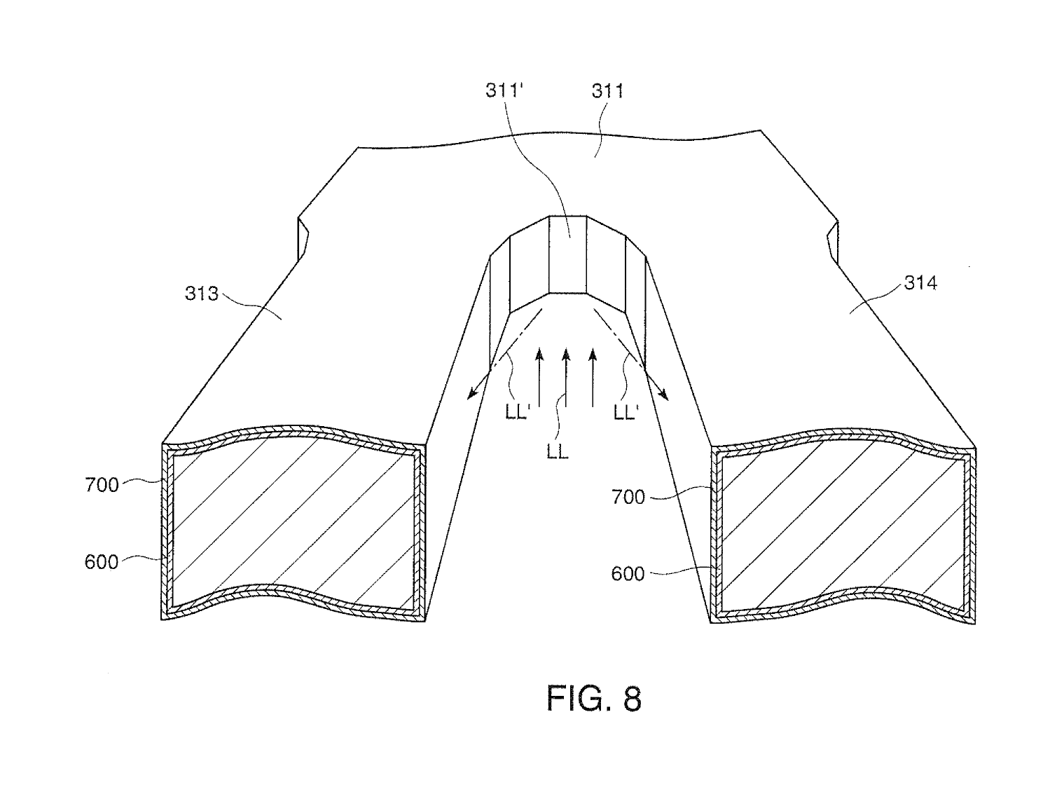

Next, as illustrated in FIG. 8, a metal film 600 is deposited on the surface of the vibration body 31 by vapor deposition or sputtering. The configuration of the metal film 600 is not particularly limited as long as it can serve as the excitation electrodes 61 and 62. For example, it is preferable that the configuration thereof be a laminated structure obtained by laminating a base layer including Ni (nickel), Cr (chromium) or the like and an electrode layer including Au (gold), Ag (silver), Cu (copper) or the like. According to such a structure, the excitation electrodes 61 and 62 having excellent adhesion to the vibration body 31 and high conductivity can be formed. Next, a photo-resist film (a positive type photo-resist film) 700 is deposited on the metal film 600.

Next, the exposure is performed by irradiating the exposure light to the photo-resist film 700 through the mask so as to correspond to a portion (a portion other than the portion to be the excitation electrodes 61 and 62) in which the metal film 600 is removed, and the exposed portion is removed with a developing solution. Therefore, the resist pattern in which the photo-resist film is formed on only the portion corresponding to the excitation electrodes 61 and 62. Then, a portion of the metal film 600 which is exposed from the resist pattern is removed by the wet etching through the resist pattern. As described above, the excitation electrodes 61 and 62 are formed in the vibration body 31.

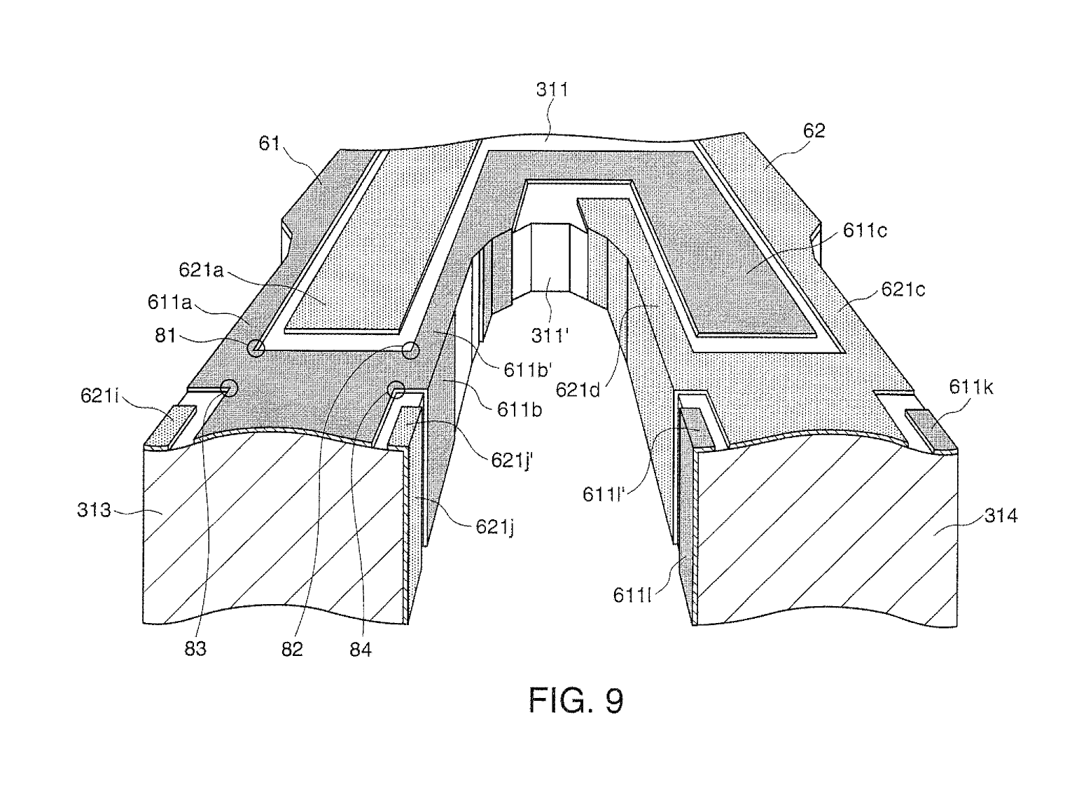

Herein, it is also necessary to irradiate the exposure light to the side surface portion of the vibration body 31 when exposing. Particularly, a side surface 311′ connecting between inner peripheral surfaces of the vibration arm 313 of the base section 311 is configured such that crystal plane of the quartz crystal is exposed and a plurality of surfaces are provided side by side, and face in different directions. Since it is necessary to irradiate the exposure light to form the wirings 613 and 623 on the side surface 311′, when exposure light LL is irradiated as illustrated in FIG. 8, there is a concern that the exposure light LL may be reflected on the side surface 311′ and the reflected exposure light LL′ may be irradiated in the inner surface of the vibration arm 313. The portion that is irradiated with the reflected exposure light LL′ is a portion to be the electrode pieces 611 (611b) so that the portion is a region on which the exposure light LL should not be irradiated under normal circumstances. As described above, when the exposure light LL is irradiated on the unintentional region of the inner surface of the vibration arms 313 and 314, for example, as illustrated in FIG. 9, the portion of the electrode piece 611b positioned on the inner surface of the vibration arm 313 is unintentionally removed and then this causes the disconnection.

However, as described above, since the vibration piece 5 is configured such that width W1 of the straddling section 611b′ formed in the first end area A1 is greater than the width W2 of the straddling section 621j′ formed in the center area A3, in other words, since the width W1 of the straddling section 611b′ formed in the first end area A1 is secured to be wide enough, it is possible to secure enough conduction by the straddling section 611b′ (it is possible to prevent the disconnection), even though removed portion is unintentionally generated as described above. In addition, in the above description, a case where the exposure light LL′ which is reflected by being irradiated in the side surface 311′ is irradiated in the inner surface of the vibration arm 313 is described; however, the invention may be applied to a case where the exposure light LL′ which is reflected by being irradiated on the side surface 311′ is irradiated in the inner surface of the vibration arm 314 or a case where the exposure light LL′ which is reflected by being irradiated in the side surface connecting between the inner peripheral surfaces of the vibration arm 313 of the base section 312 is irradiated in the inner surface of the vibration arms 313 and 314.

In addition, since the etching liquid is easily accumulated in corner sections (for example, 81 to 84 in FIG. 9 or the like) of the electrode pieces 611 and 621 during wet etching, there is a concern that the electrode pieces 611 and 621 may be peeled from the corner sections 81 to 84 in the related art; however, since the width W1 of the straddling section 611b′ formed in the first end area A1 in the vibration piece 5 is secured to be wide enough, it is possible to effectively prevent the peeling of the electrode pieces 611 and 621. Thus, it is possible to prevent the disconnection from this viewpoint.

Hereinbefore, the manufacturing method of the vibration piece 5 is described.

In addition, as described above, the value of W1 is not particularly limited; however, it is preferable that the value be 7.5 μm or more. The vibration piece 5 having W1=7.5 μm and the vibration piece 5 having W1=4 μm were made by 100 pieces, respectively, using the manufacturing method described above and then presence or not of the disconnection was checked. As a result, the vibration piece 5 which is disconnected was approximately 1% in W1=7.5 μm while the vibration piece 5 which is disconnected was approximately 10% in W1=4 μm. As described above, it has been found that it is possible to exert effectively the effect (effect of preventing the disconnection) described above by making W1 to 7.5 μm or more.

In addition, as described above, it is preferable that W1 be approximately ⅙ or less of the width of the vibration arms 313 and 314 and further preferable to be 1/10 or less. It is preferable that the width of the electrode of the electrode pieces 611 (c, d, g and h) and 621 (a, b, e and f) of the first and second end areas A1 and A2 be also a half or more of the vibration arm. The vibration piece 5 having W1 which is ⅙ of the width of the vibration arms 313 and 314 and the vibration piece 5 having W1 which is ⅕ of the width of the vibration arms 313 and 314 were made by 100 pieces, respectively, using the manufacturing method described above and then vibration efficiency was measured from the CI value. As a result, the CI value of the vibration piece 5 having W1 which is ⅕ of the width of the vibration arms 313 and 314 is worsened by approximately average 20% with respect to the CI value of the vibration piece 5 of ⅙. As described above, it has been found that it is possible to exert excellent vibration efficiency by making W1 to approximately ⅙ or less of the width of the vibration arms 313 and 314.

### Electronic Apparatus

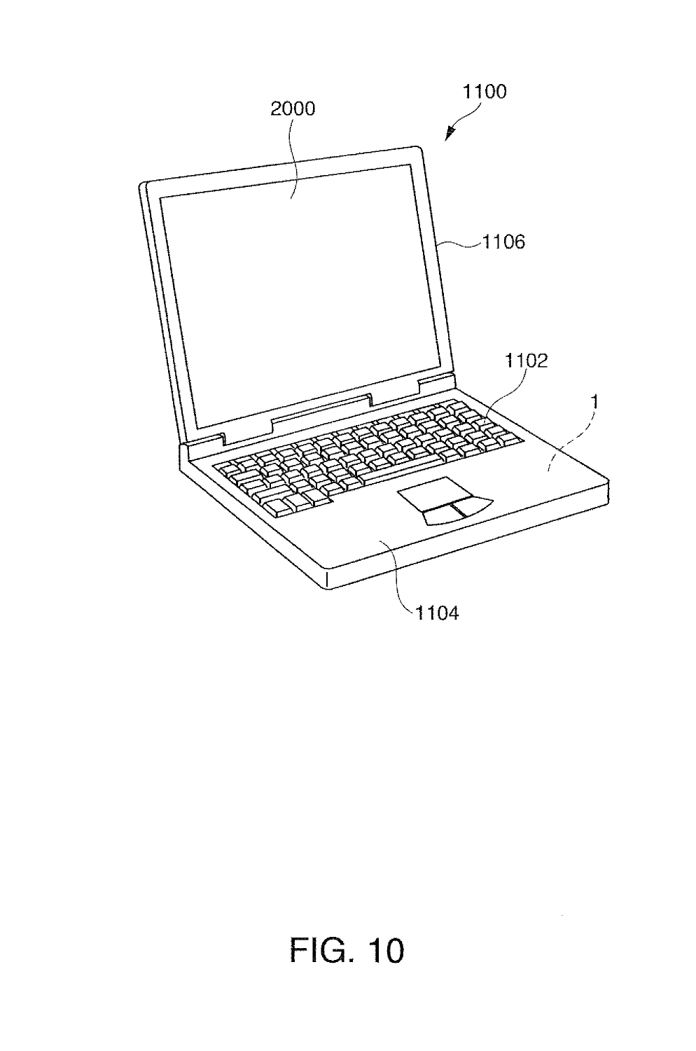

Next, an electronic apparatus (an electronic apparatus according to the invention) to which an electronic device according to the invention is applied is described in detail, based on FIGS. 10 to 13.

FIG. 10 is a perspective view illustrating a configuration of a mobile type (or notebook type) personal computer to which the electronic apparatus including the electronic device according to the invention is applied. In the drawing, a personal computer 1100 is configured with a body section 1104 including a keyboard 1102 and a display unit 1106 including a display section 2000. The display unit 1106 is rotatably supported on the body section 1104 via a hinge structure. The pressure sensor 1 for detecting an external pressure or a pressing force of a finger during operation is built in the personal computer 1100 described above.

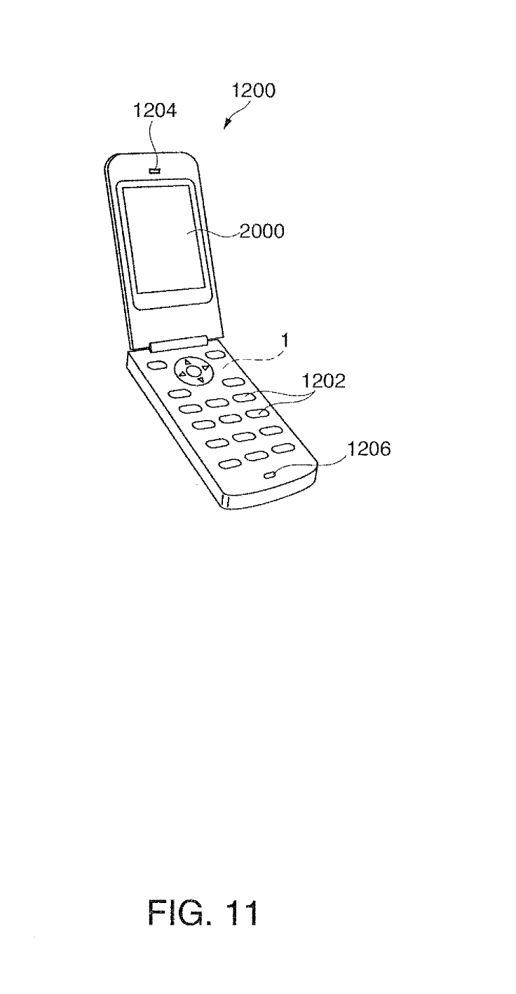

FIG. 11 is a perspective view illustrating a configuration of a cellular phone (also including PHS) to which the electronic apparatus including the electronic device according to the invention is applied. In the drawing, a cellular phone 1200 includes a plurality of operation buttons 1202, an ear piece 1204 and a mouth piece 1206, and a display section 2000 is disposed between the operation buttons 1202 and the ear piece 1204. The pressure sensor 1 for detecting the external pressure or the pressing force of the finger during operation is built in the cellular phone 1200 described above.

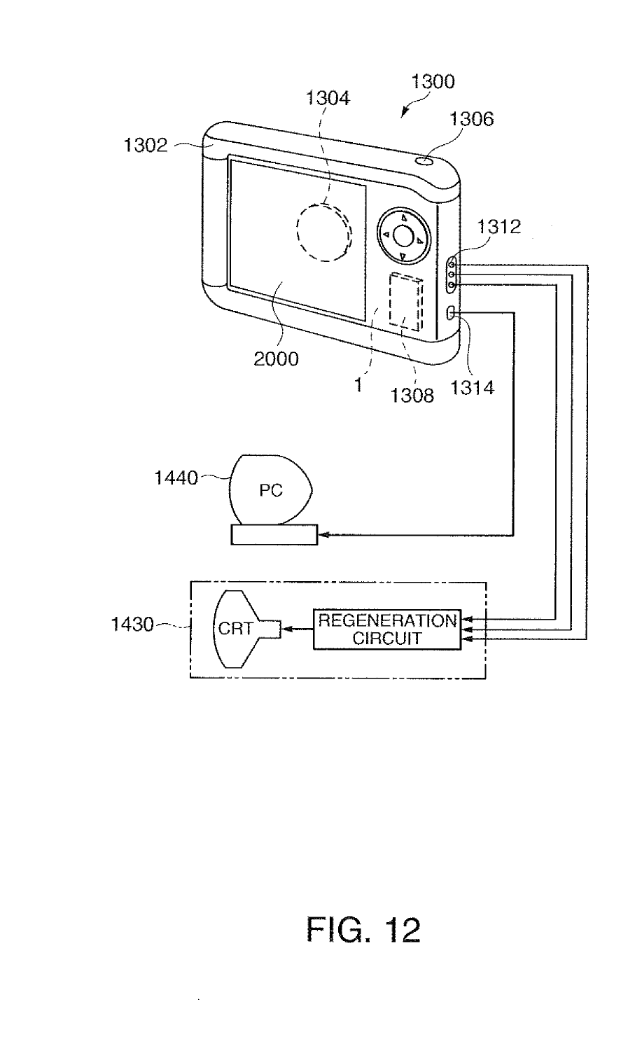

FIG. 12 is a perspective view illustrating a configuration of a digital still camera to which the electronic apparatus including the electronic device according to the invention is applied. In addition, in the drawing, connection to external apparatuses is briefly illustrated. Herein, in a normal camera, a silver salt photograph film is photosensitive by an optical image of an object while a digital still camera 1300 generates imaging signal (image signal) through photoelectric conversion of the optical image of the object by an imaging device such as CCD (Charge Coupled Device).

The digital still camera 1300 is configured such that a display section is provided on a rear surface of a case (body) 1302 and the display is performed by the CCD based on the imaging signal. The display section functions as a finder displaying the object as an electronic image. In addition, a light receiving unit 1304 including an optical lens (an imaging optical system), the CCD or the like is provided on the front side (the rear side in the drawing) of the case 1302.

In the digital still camera 1300 described above, when a photographer checks the object image displayed on the display section and presses a shutter button 1306, the imaging signal of the CCD at that time is transmitted and stored in a memory 1308. In addition, in the digital still camera 1300, a video signal output terminal 1312 and a data communication input-output terminal 1314 are provided on the side surface of the case 1302. Then, as illustrated in the drawing, the video signal output terminal 1312 is connected to a television monitor 1430 and the data communication input-output terminal 1314 is connected to a personal computer 1440, respectively if necessary. Furthermore, the digital still camera is configured such that the imaging signal stored in the memory 1308 is output to the television monitor 1430 or the personal computer 1440 with a predetermined operation. The pressure sensor 1 for detecting the external pressure or the pressing force of the finger during operation is built in the digital still camera 1300 described above.

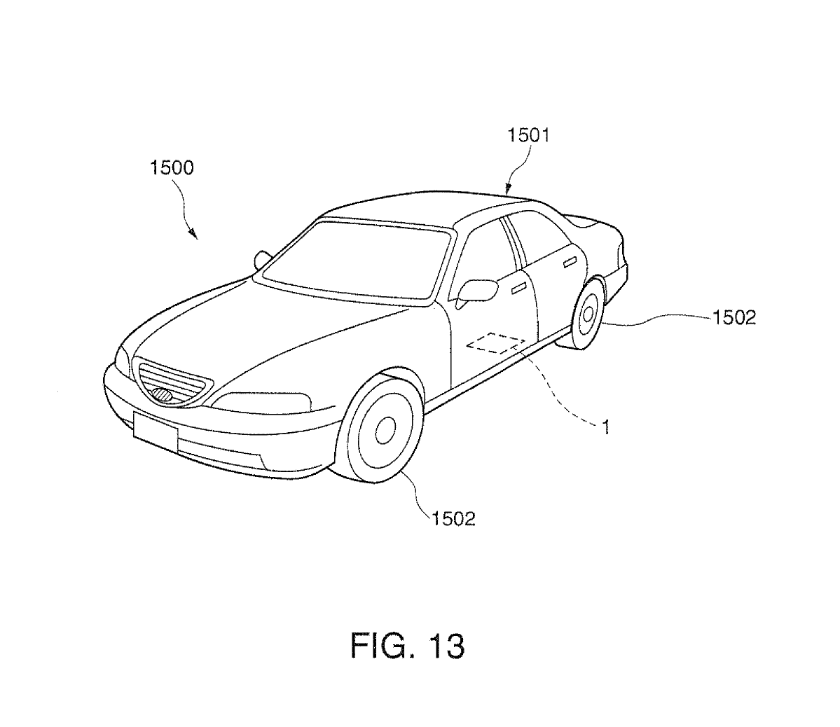

FIG. 13 is a perspective view illustrating a configuration of a mobile (vehicle) to which the electronic apparatus including the electronic device according to the invention is applied. A vehicle 1500 has a vehicle body 1501 and four wheels 1502, and is configured such that the wheels 1502 are rotated by an engine (not illustrated) provided in the vehicle body 1501. The pressure sensor 1 is built in the vehicle 1500 described above. The pressure sensor 1 can also be applied as an inclinometer for detecting the inclination of the vehicle body 1501 or as an angular velocity sensor for detecting acceleration of the vehicle body 1501. In addition, for example, a posture of the vehicle body 1501 can be detected, based on the signal from the pressure sensor 1 and hardness of the suspension can be controlled or brake of wheels 1502 can be controlled individually according to the detection result. In addition, electronic parts described above may be utilized in a biped robot or a radio control helicopter.

In addition, the electronic apparatus including the electronic device according to the invention can be applied to, for example, an ink jet type ejecting apparatus (for example, an ink jet printer), a laptop personal computer, a television, a video camera, a video tape recorder, a car navigation apparatus, a pager, an electronic diary (also including communication function), an electronic dictionary, an electronic calculator, an electronic game apparatus, a word processor, a workstation, a television telephone, a security television monitor, an electronic binoculars, a POS terminal, a medical apparatus (for example, an electronic thermometer, a blood pressure monitor, a blood glucose meter, an electrocardiogram measuring apparatus, an ultrasonic diagnostic apparatus and an electronic endoscope), a fish finder, various measuring apparatuses, a measurement equipment (for example, a measurement equipment for a vehicle, an aircraft and a ship), a flight simulator or the like, in addition to the personal computer (the mobile type personal computer) in FIG. 10, the cellular phone in FIG. 11, the digital still camera in FIG. 12 and the mobile in FIG. 13.

Hereinbefore, the vibration piece, the electronic device and the electronic apparatus according to the invention are described based on the illustrated embodiments; however, the invention is not limited to the embodiments. A configuration of each section can be replaced with any configuration having a similar function.

In addition, in the embodiments described above, the configuration in which the vibration body layer (the vibration body) is configured of the quartz crystal is described; however, the invention is not limited to the quartz crystal as the configuration material of the vibration body layer and the vibration body layer can be configured of, for example, a piezoelectric material such as lithium tantalate, lithium niobate, lithium borate, barium titanate in addition to the quartz crystal.

In addition, in the embodiments described above, the vibration arm of the vibration piece is divided into three vibration areas (the first end area, the second end area and the center area) in the longitudinal direction; however, the invention is not limited to the embodiments and the vibration arm racy be divided into five areas. In other words, the invention may be configured such that the center area is divided into a first center area, a second center area and a third center area along the extension direction of the vibration arm. Also in this case, one electrode piece and another electrode piece are disposed alternately in the longitudinal direction of the vibration arm.

The entire disclosure of Japanese Patent Application No. 2012-173748, filed Aug. 6, 2012 is expressly incorporated by reference herein.

What is claimed is:

1. A vibration piece comprising:
two base sections which are disposed with spaces in between each other; and
a vibration arm which is disposed between the two base sections to extend from one base section to the other base section and to connect the two base sections, and has vibration areas including a pair of end areas positioned on both end sides in an extending direction and a center area positioned between the pair of end areas,
wherein electrode pieces, which straddle from a side surface of the vibration arm to a main surface connecting with the side surface, are disposed in the pair of the end areas and the center area, respectively, and an average width of the electrode piece on the main surface in the end areas is greater than an average width of the electrode pieces on the main surface in the center area.

2. The vibration piece according to claim 1,
wherein the widths of the electrode pieces on the main surfaces in the end areas and the center area are constant along the extending direction of the vibration arm.

3. The vibration piece according to claim 1,
wherein when the average width of the width of the electrode pieces on the main surfaces in the end areas is W and the average width of the end areas of the vibration arm is W′, a relationship of 0<W≦W′/6 is satisfied.

4. The vibration piece according to claim 1,
wherein the average width of the electrode piece on the main surface is 7.5 μm or more.

5. The vibration piece according to claim 1, wherein the vibration area is configured with three areas of the pair of end areas and the center area.

6. An electronic device comprising:
two base sections which are disposed with spaces in between each other; and
a vibration arm which is disposed between the two base sections to extend from one base section to the other base section and to connect the two base sections, and has vibration areas including a pair of end areas positioned on both end sides in an extending direction and a center area positioned between the pair of end areas,
wherein electrode pieces, which straddle from the side surface of the vibration arm to a main surface connecting a side surface, are disposed in the pair of the end areas and the center area, respectively, and an average width of the electrode pieces on the main surface in the end areas is greater than an average width of the electrode pieces on the main surface in the center area.

7. The electronic device according to claim 6,
wherein the electronic device is a pressure detecting element including:
a diaphragm layer having a diaphragm; and
the vibration piece which is fixed to the diaphragm.

8. An electronic apparatus comprising:
two base sections which are disposed with spaces in between each other; and
a vibration arm which is disposed between the two base sections to extend from one base section to the other base section and to connect the two base sections, and has vibration areas including a pair of end areas positioned on both end sides in an extending direction and a center area positioned between the pair of end areas,
wherein electrode pieces, which straddle from the side surface of the vibration arm to a main surface connecting with a side surface, is disposed in the pair of the end areas and the center area, respectively, and an average width of the electrode pieces on the main surface in the end areas is greater than an average width of the electrode pieces on the main surface in the center area.
